(19) United States
(12) Patent Application Publication
(10) Pub. No.: US 2026/0011632 A1
(43) Pub. Date: Jan. 8, 2026

(54) SUBSTRATE STRUCTURE

(71) Applicant: SILICONWARE PRECISION INDUSTRIES CO., LTD., Taichung City (TW)

(72) Inventors: Chung-Yan HUANG, Taichung City (TW); Yu-Tung YAO, Taichung City (TW); Jann-Tzung LIU, Taichung City (TW); Shu-Yu KO, Taichung City (TW); Hsiu-Fang CHIEN, Taichung City (TW)

(73) Assignee: SILICONWARE PRECISION INDUSTRIES CO., LTD., Taichung City (TW)

(21) Appl. No.: 18/802,240

(22) Filed: Aug. 13, 2024

(30) Foreign Application Priority Data
Jul. 2, 2024 (TW) 113124710

(51) Int. Cl. H01L 23/498

(52) U.S. Cl. CPC H01L 23/49838; H01L 23/49827

(57) ABSTRACT

A substrate structure includes an insulating layer and a circuit structure disposed on an upper surface of the insulating layer. The upper surface of the insulating layer includes a chip placement region for placing a chip. The circuit structure includes a first circuit located outside the chip placement region and having a first conductive trace, and a second circuit located within the chip placement region and having a second conductive trace. A width of a region covered by the second circuit is greater than a width of the first circuit. Therefore, the width of the region covered by the circuit passing through the chip placement region is widened and is greater than the width of the circuit outside the chip placement region, thereby increasing the contact area between the chip and the circuit, and dispersing the reaction force from the circuit that the chip receives during hot pressing process.

### BACKGROUND

### 1. Technical Field

The present disclosure relates to a substrate structure, and more particularly, to a substrate structure for semiconductor components.

### 2. Description of Related Art

With the vigorous development of portable electronic products in recent years, the development of various related products is also oriented towards the trend of high density, high performance, light, thin, short and small. As a result, the semiconductor industry has developed a variety of packaging styles that integrate multiple functions to meet the requirements of thin, lightweight, and high-density electronic products. Under the influence of this trend, the width of wires on substrates used for semiconductor components is also increasingly reduced, so that more circuits and components can be accommodated on the same area of substrate.

However, as shown in FIG. 1, when a conventional semiconductor structure 1 is undergoing a molding or hot pressing process, the mold or hot pressing jig (not shown) will exert a downward force on a chip 10 toward a substrate 11. After the chip 10 is pressed down, wires 12 in the circuit of the substrate below will be pressed downward, so the wires 12 exert a reaction force on the chip 10. Since the line width of the wires 12 in the existing circuits is extremely small, the contact surface with the chip 10 is also extremely small, resulting in extremely concentrated reaction force or stress exerted by the wires 12 on the chip 10. Especially the position where the chip 10 is in contact with those long straight wires 12. Therefore, the chip 10 is susceptible to cracking at corresponding locations during the molding or hot pressing process.

Therefore, how to overcome the above-mentioned problems of the prior art has become an urgent issue to be solved.

### SUMMARY

In view of the various deficiencies of the prior art, the present disclosure provides a substrate structure, which comprises: an insulating layer having an upper surface defining a chip placement region for placing a chip; and a circuit structure disposed on the upper surface of the insulating layer, wherein the circuit structure includes a first circuit located outside the chip placement region and having a first conductive trace, and a second circuit located within the chip placement region and having a second conductive trace, wherein the first circuit is connected to the second circuit, and a width of a region covered by the second circuit is greater than a width of the first circuit.

In the aforementioned substrate structure, a width of the second conductive trace is greater than a width of the first conductive trace.

In the aforementioned substrate structure, the second conductive trace meanders through the chip placement region.

In the aforementioned substrate structure, the second circuit comprises a plurality of the second conductive traces.

In the aforementioned substrate structure, the second circuit further comprises at least a third conductive trace, and the third conductive trace has or has no electrical function.

In the aforementioned substrate structure, the second circuit further comprises at least an expansion portion, and the expansion portion is connected to the second conductive trace.

The present disclosure further provides a substrate structure, which comprises: an insulating layer having an upper surface defining a chip placement region for placing a chip; a circuit structure disposed on the upper surface of the insulating layer, wherein the circuit structure includes at least a first circuit disposed outside the chip placement region, two second circuits disposed within the chip placement region, and at least a third circuit disposed on a lower surface of the insulating layer, wherein the second circuits are spaced apart, one end of each of the second circuits is located in the chip placement region, and the other end of each of the second circuits is connected to the first circuit; and a plurality of conductive vias formed in the insulating layer, wherein the two second circuits are electrically connected to the third circuit via the plurality of conductive vias.

In the aforementioned substrate structure, each of the second circuits has a single conductive trace or a plurality of conductive traces.

As can be seen from the above, in the substrate structure of the present disclosure, the circuit structure is disposed on the insulating layer, and the width of the region covered by the circuit passing through the chip placement region is widened and is greater than the width of the circuit outside the chip placement region, so as to increase the contact area between the chip and the circuit, and disperse the reaction force from the circuit that the chip receives during the hot pressing process. Therefore, the risk of chip damage during the hot pressing process can be reduced, and the manufacturing yield of semiconductor components with this substrate structure can be improved.

### BRIEF DESCRIPTION OF THE DRAWINGS

FIG. 1 is a partial cross-sectional schematic view of a conventional semiconductor package.

FIG. 2A is a partial top view of a substrate structure according to a first embodiment of the present disclosure.

FIG. 2B, FIG. 2C, FIG. 2D-1 and FIG. 2E-1 are partial top views of various variations according to the first embodiment of the present disclosure.

FIG. 2D-2 is a partial top view of a different variation of FIG. 2D-1.

FIG. 2E-2 to FIG. 2E-5 are partial top views of different variations of FIG. 2E-1.

FIG. 3A-1 and FIG. 3B-1 are respectively a partial top view and a partial bottom view of the substrate structure according to a second embodiment of the present disclosure.

FIG. 3A-2 and FIG. 3B-2 are respectively a partial top view and a partial bottom view of a variation according to the second embodiment of the present disclosure.

FIG. 3C is a partial cross-sectional schematic view of the substrate structure according to the second embodiment of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “lower,” “a,” “one,” “first,” “second,” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

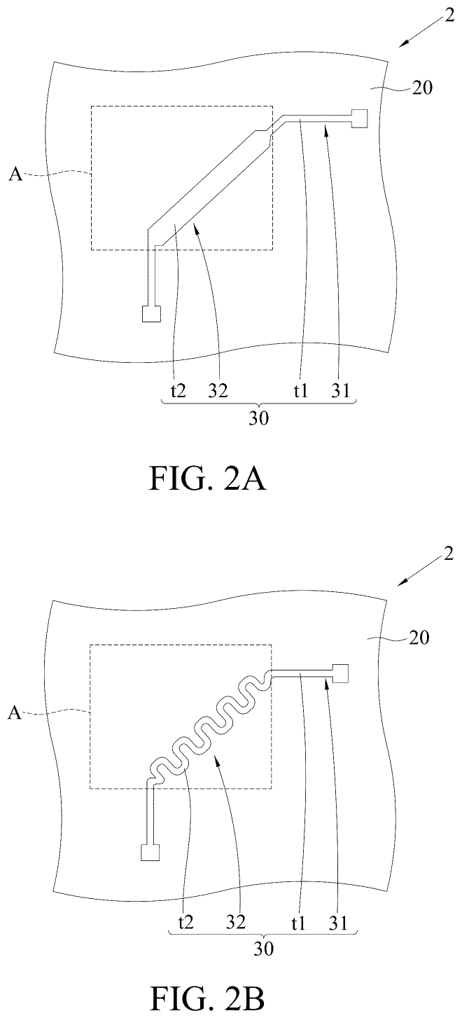

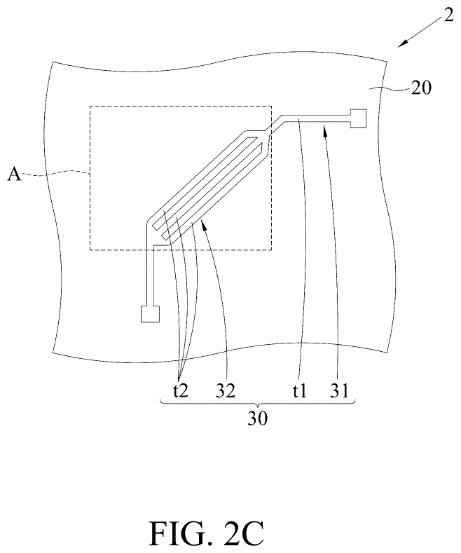

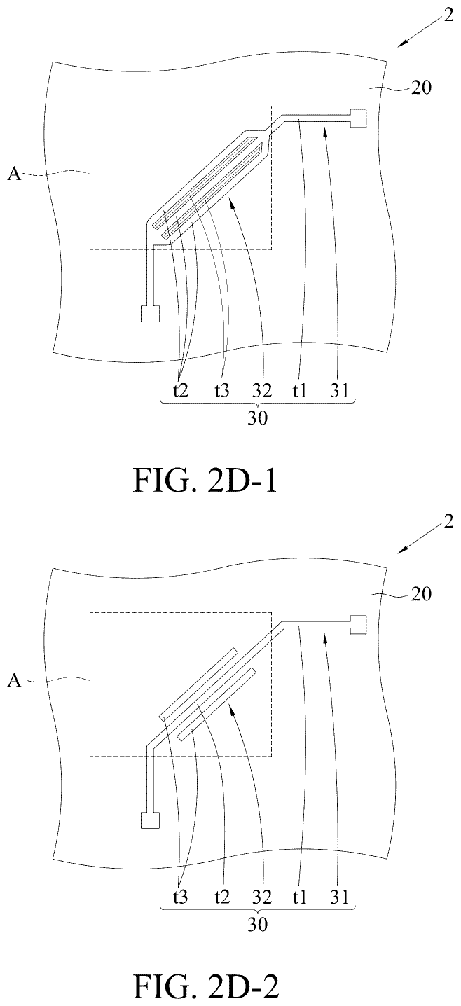

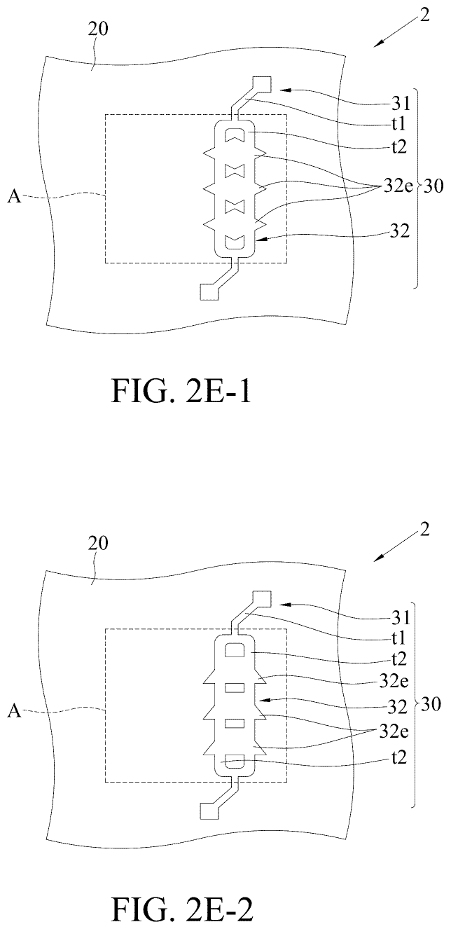

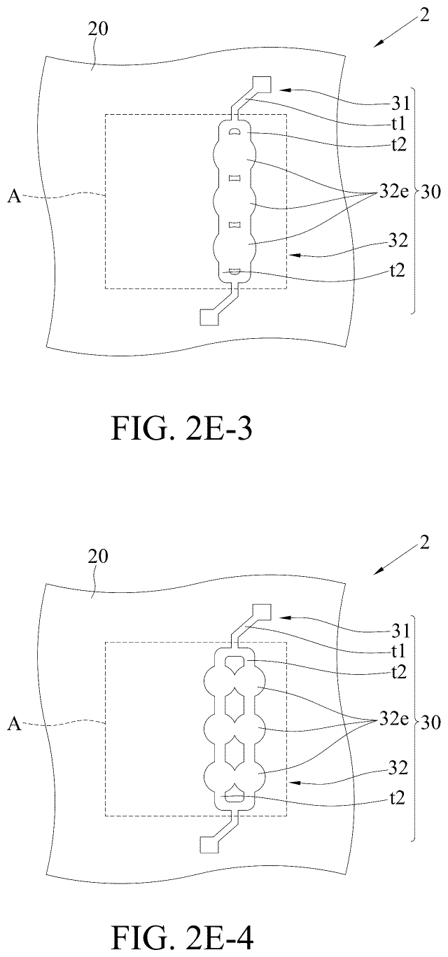

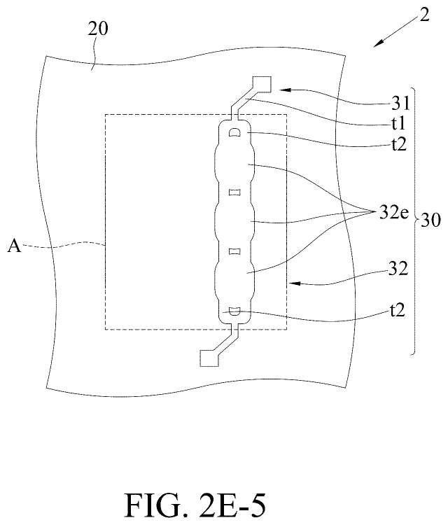

FIG. 2A is a partial top view of a substrate structure according to a first embodiment of the present disclosure. As shown in FIG. 2A, a substrate structure 2 includes: an insulating layer 20, wherein an upper surface of the insulating layer 20 defines a chip placement region A for placing a chip; and a circuit structure 30. The insulating layer 20 is made of dielectric material, such as polybenzoxazole (PBO), polyimide (PI), prepreg, etc. However, the insulating layer 20 can also be made of any other insulating material that meets the requirements, and the present disclosure is not particularly limited to as such.

The chip placement region A is used to place a chip (not shown), such as an active semiconductor component or a passive semiconductor component. Likewise, the present disclosure is not particularly limited to as such.

The circuit structure 30 includes a plurality of circuits. In one embodiment, the circuit structure 30 includes at least a first circuit 31 located outside the chip placement region A, and a second circuit 32 located within the chip placement region A, wherein the first circuit 31 and the second circuit 32 are electrically connected to each other and together form the circuit structure 30. The first circuit 31 includes a first conductive trace t1, and the second circuit 32 includes a second conductive trace t2. Generally speaking, the first conductive trace t1 and the second conductive trace t2 are made of materials with good conductivity such as copper or copper-containing alloy. The width of the region covered by the second circuit 32 is greater than the width of the first circuit 31. For example, the second circuit 32 may contain only one second conductive trace t2, and the width of the second conductive trace t2 is greater than the width of the first conductive trace t1 of the first circuit 31 connected in front of the second circuit 32. That is to say, the circuit structure 30 extends from the first circuit 31 with the first conductive trace t1 having a narrower width outside the chip placement region A into the chip placement region A, and then transforms into a second circuit 32 with a second conductive trace t2 having a wider width. In this way, when a chip (not shown) is placed in the chip placement region A, the second circuit 32 composed of the wider second conductive trace t2 is in contact with the bottom of the chip. During the subsequent hot pressing or compression molding process, since the second conductive trace t2 in the second circuit 32 has a wider contact surface with the bottom surface of the chip, the reaction force or stress exerted on the bottom surface of the chip by the second conductive trace t2 in the second circuit 32 can be dispersed over a larger area. Therefore, the risk of chip cracking there can be effectively reduced, thereby improving the manufacturing yield of semiconductor components or electronic packages having the substrate structure 2.

It should be noted that although this embodiment uses a single-layer single-sided substrate structure 2 with only one insulating layer and one circuit structure 30 as an example, in some other implementations, one or more insulating layers (not shown) can be added below the insulating layer 20, and at least a build-up circuit structure (not shown) is disposed between any two adjacent insulating layers to form a multi-layer structure, but the present disclosure is not particularly limited to as such. However, because there is no mechanical connection between these added insulating layers and built-up circuit structures and the chip located in the chip placement region A, no force will be directly exerted on the chip during the hot pressing process, so these additional structures will not be described in detail here.

In addition to the above-mentioned implementation, there can also be a variation of the implementation as shown in FIG. 2B. The second conductive trace t2 in the second circuit 32 meanders through the chip placement region A. In this way, the width of the region covered by the second circuit 32 can also be made greater than the width of the first circuit 31, so that there is a wider/larger contact surface between the second circuit 32 and the chip (not shown) located in the chip placement region A. This prevents the second circuit 32 in the circuit structure 30 from exerting excessively concentrated reaction force or stress on the bottom surface of the chip and damaging the chip during the hot pressing process.

Or as shown in FIG. 2C, in another variation of the implementation, the second circuit 32 located in the chip placement region A includes a plurality of second conductive traces t2, whereby the width of the area covered by the second circuit 32 having the plurality of second conductive traces t2 is greater than the width of the first circuit 31 located outside the chip placement region A. Therefore, the reaction force or stress exerted by the second circuit 32 on the chip (not shown) disposed above the second circuit 32 can also be dispersed in the subsequent hot pressing process.

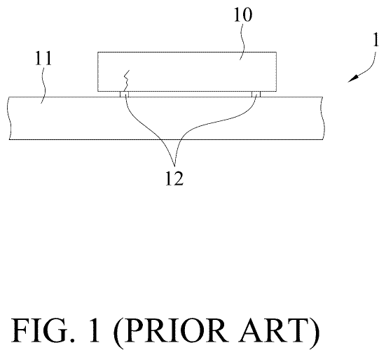

As shown in FIG. 2D-1, in yet another variation of the implementation, the second circuit 32 further includes at least a third conductive trace t3. Here, the second circuit 32 is provided with three second conductive traces t2 and two third conductive traces t3 as an example. The third conductive trace t3 may be a conductive trace with electrical function, for example, it is connected in parallel with the second conductive trace t2; alternatively, the third conductive trace t3 may have only one end connected to the second conductive trace t2 and the other end may be open circuit, or the third conductive trace t3 may even be a dummy conductive trace with both ends open and having no electrical function as shown in FIG. 2D-1. However, regardless of whether it has electrical function or not, adding a third conductive trace t3 in the second circuit 32 can also achieve the same effect as the aforementioned implementations, so the explanation will not be repeated here.

In addition, as shown in FIG. 2D-2, the second circuit 32 may also include only one second conductive trace t2 electrically connected to the first circuit 31 and at least one third conductive trace t3 that has no electrical function (the implementation in FIG. 2D-2 has two third conductive traces t3). The implementation shown in FIG. 2D-2 can be regarded as a variation of the implementation of FIG. 2D-1 and will not be further described.

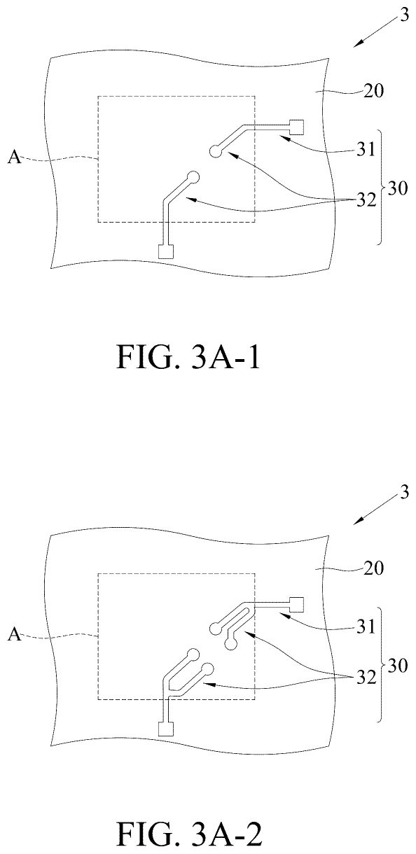

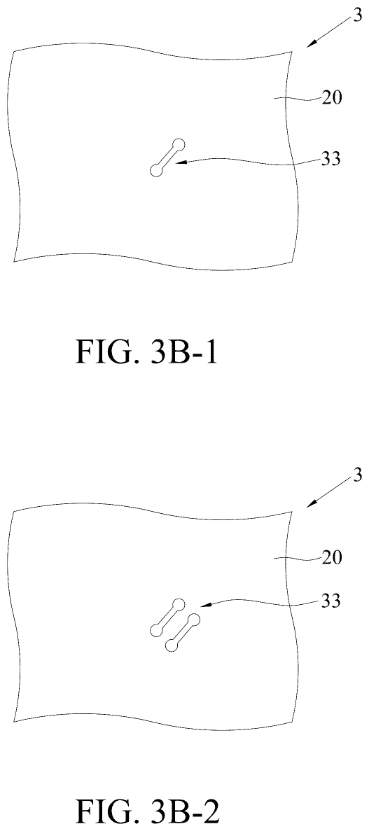

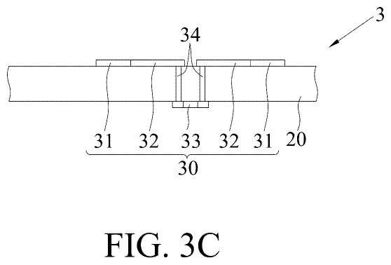

In addition, as shown in FIG. 2E-1 and FIG. 2E-2 to FIG. 2E-5, the second circuit 32 may further include at least an expansion portion 32e. The expansion portion 32e may be a metal block electrically connected to the second conductive trace t2 and disposed on the surface of the insulating layer 20. Alternatively, in a multi-layer circuit structure, the expansion portion 32e may also be a conductive via (not shown) connecting the second circuit 32 on the upper surface of the insulating layer 20 with circuits in other layers (not shown). However, in the examples shown in FIG. 2E-1 and FIG. 2E-2 to FIG. 2E-5, the second circuit 32 includes two second conductive traces t2 and includes three expansion portions 32e connected across the two second conductive traces t2, wherein the difference only lies in the shape of the expansion portion 32e. For instance, each expansion portion 32e shown in FIG. 2E-1 is a rhombus, each expansion portion 32e shown in FIG. 2E-2 is a trapezoid, each expansion portion 32e shown in FIG. 2E-3 is a circle, each expansion portion 32e shown in FIG. 2E-4 includes two overlapping circles, while each expansion portion 32e shown in FIG. 2E-5 is an oblong circle. Of course, the expansion portion 32e can also be in any other shape, as long as the width of the range covered by the second circuit 32 can be greater than the width of the first circuit 31.

FIG. 3A-1 and FIG. 3B-1 are respectively a partial top view and a partial bottom view according to a second embodiment of the present disclosure, and FIG. 3C is a partial cross-sectional schematic view according to the second embodiment of the present disclosure. As shown in FIG. 3A-1, FIG. 3B-1 and FIG. 3C, the present disclosure further provides a substrate structure 3, which comprises: an insulating layer 20, wherein an upper surface of the insulating layer 20 defines a chip placement region A for placing a chip; a circuit structure 30 including at least a first circuit 31 disposed outside the chip placement region A on the upper surface of the insulating layer 20, two second circuits 32 disposed in the chip placement region A and a third circuit 33 disposed on a lower surface of the insulating layer 20, wherein each of the second circuits 32 only has a single conductive trace, one end of one of the second circuits 32 is spaced apart from one end of the other one of the second circuits 32 in the chip placement region A, and the other end of each of the second circuits 32 is connected to the first circuit 31; and a plurality of conductive vias 34 disposed in the insulating layer 20, wherein the two second circuits 32 are electrically connected to the third circuit 33 via the plurality of conductive vias 34. That is to say, the substrate structure 3 shown in this embodiment shortens the length of the second circuit 32 that will subsequently exert a reaction force on the bottom of the chip (not shown) by changing the layout of the second circuit 32 in the chip placement region A, so as to reduce the reaction force or stress on the bottom surface of the chip. This can also reduce the risk of the chip cracking due to stress on the bottom during the hot pressing process.

Also, in a variation of the implementation shown in FIG. 3A-2 and FIG. 3B-2, the circuit structure 30 includes two second circuits 32 spaced apart in the chip placement region A, and each second circuit 32 is divided into two conductive traces to increase the width of the region covered by the second circuit 32. Meanwhile, each conductive trace in each second circuit 32 is electrically connected to the third circuit 33 disposed on the lower surface of the insulating layer 20 via a conductive via 34 penetrating through the insulating layer 20. In this way, the length of the second circuit 32 that will subsequently exert a reaction force on the bottom of the chip (not shown) can be shortened by changing the layout of the second circuit 32 in the chip placement region A, and the reaction force or stress on the bottom surface of the chip can be reduced, thereby reducing the risk of the chip cracking due to stress on the bottom during, for example, a hot pressing process.

To sum up, in the substrate structure of the present disclosure, the circuit structure is disposed on the insulating layer, and the width of the region covered by the circuit passing through the chip placement region is widened and is greater than the width of the circuit outside the chip placement region, so as to increase the contact area between the chip and the circuit, and disperse the reaction force from the circuit that the chip receives during the hot pressing process. Therefore, the risk of chip damage during the hot pressing process can be reduced, and the manufacturing yield of semiconductor components with this substrate structure can be improved.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A substrate structure, comprising:
an insulating layer having an upper surface defining a chip placement region for placing a chip; and
a circuit structure disposed on the upper surface of the insulating layer, wherein the circuit structure includes a first circuit located outside the chip placement region and having a first conductive trace, and a second circuit located within the chip placement region and having a second conductive trace, wherein the first circuit is connected to the second circuit, and a width of a region covered by the second circuit is greater than a width of the first circuit.

2. The substrate structure of claim 1, wherein a width of the second conductive trace is greater than a width of the first conductive trace.

3. The substrate structure of claim 1, wherein the second conductive trace meanders through the chip placement region.

4. The substrate structure of claim 1, wherein the second circuit comprises a plurality of the second conductive traces.

5. The substrate structure of claim 1, wherein the second circuit further comprises at least a third conductive trace, and the third conductive trace has or has no electrical function.

6. The substrate structure of claim 1, wherein the second circuit further comprises at least an expansion portion, and the expansion portion is connected to the second conductive trace.

7. A substrate structure, comprising:
an insulating layer having an upper surface defining a chip placement region for placing a chip;
a circuit structure disposed on the upper surface of the insulating layer, wherein the circuit structure includes at least a first circuit disposed outside the chip placement region, two second circuits disposed within the chip placement region, and at least a third circuit disposed on a lower surface of the insulating layer, wherein the second circuits are spaced apart, one end of each of the second circuits is located in the chip placement region, and the other end of each of the second circuits is connected to the first circuit; and
a plurality of conductive vias formed in the insulating layer, wherein the two second circuits are electrically connected to the third circuit via the plurality of conductive vias.

8. The substrate structure of claim 7, wherein each of the second circuits has a single conductive trace.

9. The substrate structure of claim 7, wherein each of the second circuits has a plurality of conductive traces.
